(19) United States
(12) Patent Application Publication
(10) Pub. No.: US 2008/0042775 A1
(43) Pub. Date: Feb. 21, 2008

(54) DESIGN FOR TRANSMISSION LINE ON OVER SPLIT PLANE STRUCTURE

(75) Inventors: Chih-Ming Yang, Taipei (TW); Yen-Hao Chen, Taipei (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: INVENTEC CORPORATION, Taipei (TW)

(21) Appl. No.: 11/465,408

(22) Filed: Aug. 17, 2006

(51) Int. Cl. H01P 5/02; H03H 7/38

(52) U.S. Cl. 333/34

(57) ABSTRACT

A design for a transmission line on an over split plane structure is provided, which optimizes the line length and line width of the line segment of transmission line part connected to the over split plane structure by using a concept of impedance match, such that this part of line segment behaves with a capacitive low impedance characteristic, achieving the impedance match at a designed frequency point, and thereby eliminating a discontinuous effect caused by a high impedance characteristic of the electrical property of transmission line on the over split plane structure.

### BACKGROUND OF THE PRESENT INVENTION

1. Field of Invention

The present invention relates to a transmission line, and more particularly to a transmission line for an over split plane structure.

2. Related Art

Layout is one of the designs for a printed circuit board (PCB), the quality of which directly influences the property of the entire system, and most of the design theories for a high-speed circuit is realized and verified also through the layout eventually. Accordingly, the layout is critical in the design for the high-speed PCB.

In the design for a multiple-layer PCB, a less layer number must be used for completing the layout of the entire board due to a need for saving the cost, so different voltage levels must be cut on a limited power layer, and thus, if the transmission line crosses over the different voltage cut surfaces, an over split plane structure is formed.

Referring to FIGS. 1A and 1B, FIG. 1A is a schematic view 10 of a conventional over split plane structure of transmission line, and FIG. 1B is a top view 11 of a conventional over split plane structure of transmission line, and as shown in the figures, a cut split plane 102 is provided on a PCB 101, and a transmission line 103 is used for transmitting signals and crosses over the split plane 102, wherein the line width of the transmission line 103 is W. However, since the transmission line 103 above the over split plane 102 has no signal reference plane, this part of line segment behaves with an inductive high impedance characteristic, such that the impedance of transmission line generates a discontinuous effect, resulting in that a signal reflection when a signal is transmitted to this part of line segment. In view of the above, the solution of the conventional art is to add capacitors on two cut surfaces, such that the current on the transmission line may flow back on the two cut surfaces, thereby decreasing the phenomenon of the signal reflection. However, although such a conventional art may solve the problem of the signal reflection, it increases the manufacturing cost, and also the problem of a decrease in layout space due to the increase of capacitors has to be encountered.

### SUMMARY OF THE PRESENT INVENTION

To solve the aforementioned problem, the present invention discloses a transmission line for an over split plane structure, wherein the optimized line length and line width of a single transmission line are adjusted according to an expected frequency by using a Smith chart under the concept of impedance match, so as to change the width of the line segment of transmission line part connected to the over split plane structure, such that the line segment of this part behaves with a capacitive low impedance characteristic, achieving an impedance match at a designed frequency point, and thereby eliminating a discontinuous effect caused by an inductive high impedance characteristic of the transmission line on the over split plane structure, and eliminating a loss in signal reflection.

Further scope of applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1A is a schematic view of a conventional over split plane structure;

FIG. 1B is a top view of a conventional over split plane structure;

FIG. 2A is a schematic view of changing the line length and line width of transmission line part of the present invention;

FIG. 2B is a top view of changing the line length and line width of transmission line part of the present invention;

FIG. 3 is curve diagrams of the reflection losses before and after a compensation for an impedance mismatch by increasing the line width of transmission line of the present invention; and

FIG. 4 is eye diagrams of the reflection losses before and after a compensation for an impedance mismatch by increasing the line width of transmission line of the present invention.

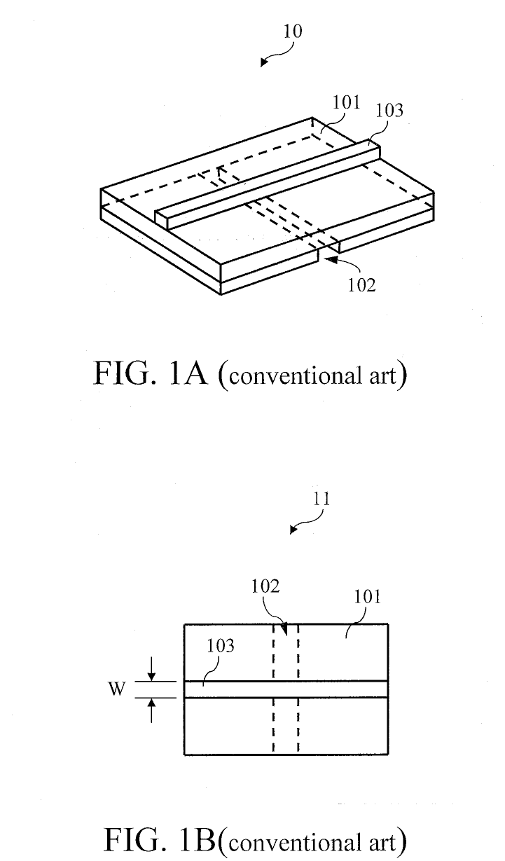

### DETAILED DESCRIPTION OF THE INVENTION

Detailed characteristics and advantages of the present invention is described in detail in the detailed description of the present invention below, the content of which is sufficient to make any skilled in the art to understand the technological content of the present invention according to which it is implemented, and any skilled in the art may easily understand the objects and advantages relating to the present invention according to the contents, claims, and drawings disclosed in the present specification.

The present invention changes a transmission line width under the concept of impedance match, such that part of the line segment of transmission line on the split plane over a PCB behaves with a capacitive low impedance characteristic, achieving an impedance match at a designed frequency point, and thereby eliminating an effect of discontinuous impedance of transmission line caused by an inductive high impedance characteristic.

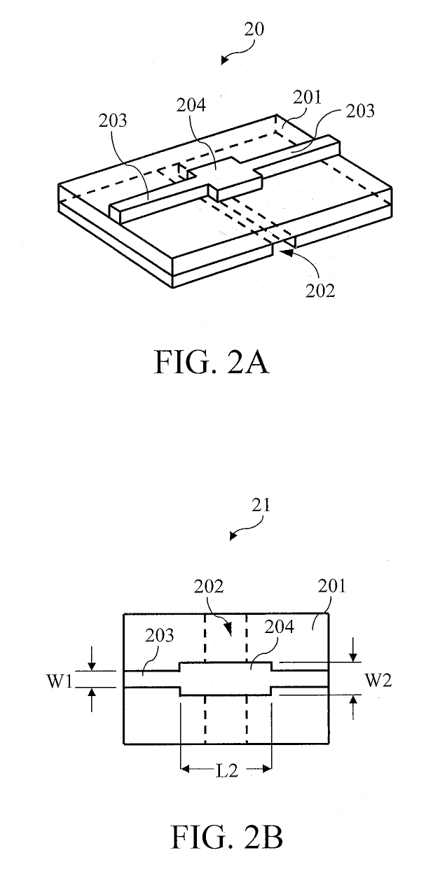

Referring to FIGS. 2A and 2B, FIG. 2A is a schematic view 20 of changing the line length and line width of transmission line part of the present invention, and FIG. 2B is a top view 21 of changing the line length and line width of transmission line part of the present invention. According to one alternative embodiment of the present invention, the optimized line length and line width of a single transmission line is adjusted according to an expected frequency by using a Smith chart to achieve an impedance match. For example, a first line segment 203 of transmission line in outer layer of a PCB 201 has a first line length L1 (not shown) and a first line width W1, and when a split plane 202 is again crossed over by the line segment of the first line width W1 of the same first line segment 203, the transmission line above the split plane 202 and the transmission line originally designed behave with an inductive high impedance characteristic from the impedance mismatch. Accordingly, the line width of transmission line above the split plane 202 needs to be increased to overcome an impedance discontinuity, and a second line segment 204 having a second line length L2 and a second line width W2 is added. The second line segment 204 with an increased line width extends towards at least one end of the transmission line by taking the split plane 202 as a center. According to an embodiment of the present invention, for example, if the line width of the first line segment 203 is realized by 7 mils (mil; one thousandth inch) while the width of the split plane 202 is 20 mils, the second line segment 204 extends by 75 mils respectively towards two ends of the transmission line, thereby forming the line segment with a second line length L2 of 150 mils and a second line width W2 of 14 mils. The length and width of line segment with an increased line width described herein is not used to limit the scope of the present invention, and those skilled in the art may change the split plane 202 and the first line length L1 and/or the first line width W1 of the first line segment 203 of transmission line, thereby changing the second line length L2 and/or the second line width W2 to be increased of the second line segment 204 of transmission line above the split plane 202. According to the embodiment of the present invention, the way of increasing the line width of transmission line for achieving an impedance match may also be applicable to single-end transmission and differential mode transmission circuits.

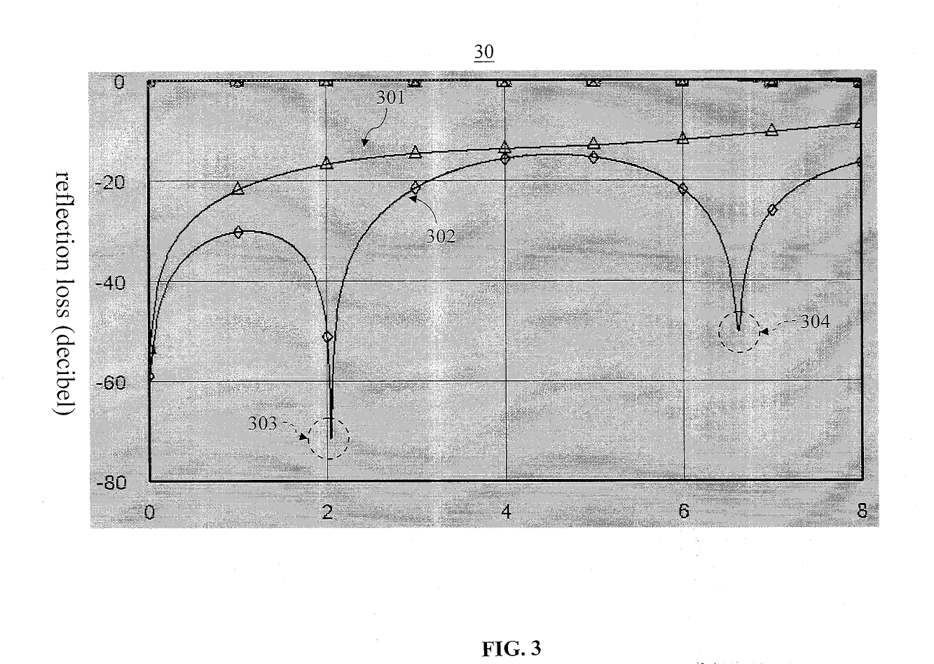

Referring to FIG. 3, it is curve diagrams 30 of the reflection losses before and after a compensation for an impedance mismatch by increasing the line width of the transmission line 203 of the present invention. The line length and line width of transmission line with a frequency of 2-8 GHz (billion Hertz) is obtained by using a Smith chart. A reflection loss curve 301 of the signal after a compensation is measured and compared with a reflection loss curve 302 of the signal of transmission line before a compensation. As shown in the figure, two resonance points 303, 304 may be generated at 2 GHz and 6.5 GHz after compensation, and the frequency of points near the two points all may decrease the reflection loss significantly.

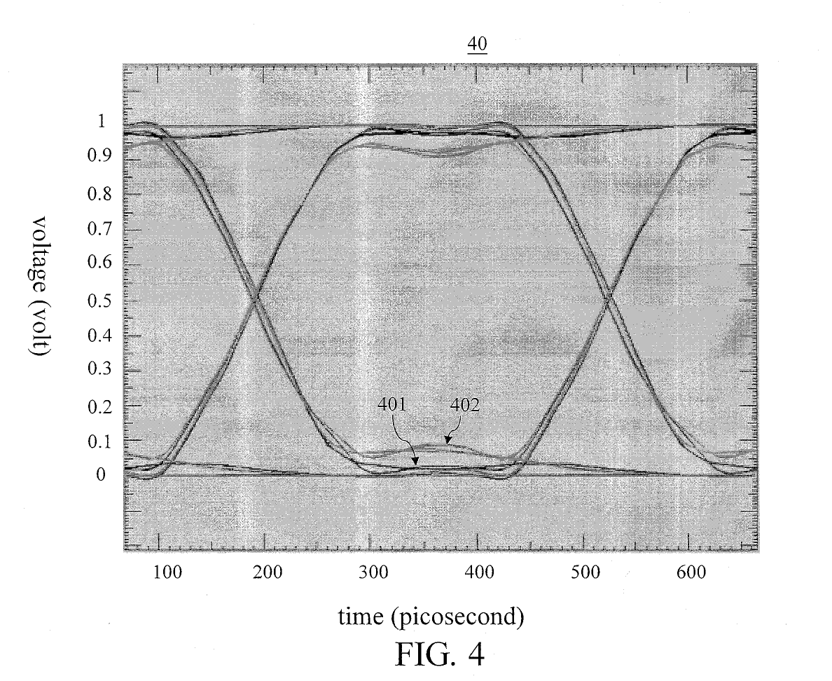

Referring to FIG. 4, it is eye diagrams 40 of the reflection losses before and after a compensation for an impedance mismatch by increasing the line width of the transmission line 203 of the present invention. The line length and line width of transmission line with a frequency of 3 GHz is obtained by using a Smith chart. An eye diagram 401 of the signal after compensation is measured and compared with an eye diagram 402 of the signal of transmission line before compensation, and the distortion of the eye diagram 402 of the signal of transmission line before compensation is higher as shown in the figure.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A design for a transmission line on an over split plane structure, the over split plane structure being a split plane disposed on a PCB, and the transmission line crossing over the split plane and comprising a first line segment with a first line length and a first line width, wherein:
the transmission line has a second line segment with a second line length and a second line width disposed above the split plane, and the second line segment extends towards at least one end of the transmission line from the position corresponding to the center of the split plane and is connected to the first line segment.

2. The design for a transmission line on an over split plane structure as claimed in claim 1, wherein the second line width is larger than the first line width.

3. The design for a transmission line on an over split plane structure as claimed in claim 1, wherein the transmission line is used for a signal-end transmission.

4. The design for a transmission line on an over split plane structure as claimed in claim 1, wherein the transmission line is used for a differential mode transmission.

5. The design for a transmission line on an over split plane structure as claimed in claim 1, wherein the second line length is 150 mils and the second line width is 14 mils.
